(19) United States
(12) Patent Application Publication
(10) Pub. No.: US 2022/0252650 A1
(43) Pub. Date: Aug. 11, 2022

(54) READOUT CIRCUIT FOR A SENSOR SYSTEM AND SENSOR SYSTEM

(71) Applicant: Robert Bosch GmbH, Stuttgart (DE)

(72) Inventors: Andrea Visconti, Muenchen (DE); Francesco Diazzi, Muenchen (DE); Luca Valli, Muenchen (DE)

(21) Appl. No.: 17/648,589

(22) Filed: Jan. 21, 2022

(30) Foreign Application Priority Data
Feb. 8, 2021 (DE) 10 2021 201 149.7

(51) Int. Cl. G01R 27/26; H03K 5/1252; G01P 3/48

(52) U.S. Cl. CPC G01R 27/2605; G01P 3/4802; H03K 5/1252

(57) ABSTRACT

A readout circuit for a capacitive differential sensor including periodic output signals. The readout circuit includes: one capacitance-to-voltage converter for output signals of the sensor; and one feedback circuit including a sampling unit and a filter unit, the sampling unit being configured to sample a differential signal of two oppositely-phased output signals of the capacitance-to-voltage converter and to generate a sampled differential signal, the filter unit being configured to average the sampled differential signals and to generate an averaged differential signal, and the feedback circuit being configured to feed the averaged differential signal as feedback into the capacitance-to-voltage converter. A sensor system including a readout circuit is also described.

### CROSS REFERENCE

The present application claims the benefit under 35 U.S.C. § 119 of German Patent Application No. DE 10 2021 201 149.7 filed on Feb. 8, 2021, which is expressly incorporated herein by reference in its entirety.

### FIELD

The present invention relates to a readout circuit for a capacitive differential sensor including periodic output signals. The present invention further relates to a sensor system including a readout circuit.

### BACKGROUND INFORMATION

MEMS gyroscope sensors are found increasingly in personal electronic devices and IOT devices. For most of these applications, the power consumption is a very critical parameter, at the same time, however, performance parameters such as noise should also be continually improved upon.

One of the most critical circuit blocks in the gyroscope system is the first readout block, which is usually implemented as a capacitance-to-voltage converter (C/V converter) and contributes significantly to the entire noise budget and, consequently, to the power budget. Such a block must include for its operation a purely integrated characteristic in the frequency range of the input signal and is therefore implemented as an amplifier with purely capacitive feedback.

One problem with C/V converters are offsets at the inputs of the C/V converter, which are based on inaccuracies in the design of the C/V converter.

### SUMMARY

It is an object of the present invention to provide an improved readout circuit for a capacitive differential sensor including a periodic output signal and an improved sensor system.

This object may be achieved by the readout circuit and the sensor system in accordance with example embodiment of the present invention. Advantageous embodiments of the present invention are disclosed herein.

According to one aspect of the present invention, a readout circuit for a capacitive differential sensor including periodic output signals is provided. In accordance with an example embodiment of the present invention, the readout circuit include at least: one capacitance-to-voltage converter for output signals of the sensor; one feedback circuit including a sampling unit and a filter unit, the sampling unit being configured to sample a differential signal of two oppositely-phased output signals of the capacitance-to-voltage converter and to generate a sampled differential signal, the filter unit being configured to average the sampled differential signal and to generate an averaged differential signal, and the feedback circuit being configured to feed the averaged differential signal as feedback into the capacitance-to-voltage converter.

This may yield the technical advantage that an improved readout circuit for a capacitive differential sensor including periodic output signals may be provided, as a result of which undesirable offsets of a capacitance-to-voltage converter of the readout circuit may be reduced or neutralized. For this purpose, the readout circuit includes, in addition to the capacitance-to-voltage converter, a feedback circuit including a sampling unit and a filter unit. Using the sampling unit, it is possible to generate a sampled differential signal of two oppositely-phased output signals of the capacitance-to-voltage converter, while it is possible with the aid of the filter unit to generate an averaged differential signal. The feedback circuit is configured to feed the averaged differential signal as feedback into the capacitance-to-voltage converter. Using the fed averaged differential signal, it is possible to reduce or to neutralize a DC voltage offset of the capacitance-to-voltage converter. The averaged differential signal of the two oppositely-phased output signals of the capacitance-to-voltage converter correspond in this case to the DC voltage offset averaged over a period of the periodic output signal of the capacitance-to-voltage converter. By feeding the averaged differential signal with a corresponding sign into the input connections of the capacitance-to-voltage converter, it is possible to reduce or neutralize the DC voltage offset occurring there. In this way, it is possible to substantially reduce the noise behavior of the capacitance-to-voltage converter and, in connection therewith, that of the entire readout circuit.

According to one specific embodiment of the present invention, the feedback circuit is further configured to superpose a common-mode voltage signal on the averaged differential signal.

This may yield the technical advantage that as a result of the common-mode voltage signal fed in addition to the averaged differential signal into the input connections of the capacitance-to-voltage converter, it is possible to bring the voltage present at the input connections of the capacitance-to-voltage converter to a predetermined value. In this way, the capacitance-to-voltage converter may be operated in a preferred operating range, which may increase the efficiency and precision of the capacitance-to-voltage converter.

According to one specific embodiment of the present invention, the sampling unit is configured to sample the differential signal at a predefined sampling frequency, the sampling frequency being at least double a frequency of the oppositely-phased output signals of the capacitance-to-voltage converter.

This may yield the technical advantage that when sampling using the sampling unit, the periodicity of the output signals of the capacitance-to-voltage converter may be taken into account. The periodicity of the output signals of the capacitance-to-voltage converter correspond in this case to the periodicity of the output signals of the sensor.

According to one specific embodiment of the present invention, the sampling unit is configured to sample the differential signal at a sampling frequency which is an integer multiple of the frequency of the output signals.

This may yield the technical advantage that the periodicity of the output signals may be taken into account by sampling with the aid of the sampling unit. In this way, it is possible to ascertain precisely the DC voltage offset of the oppositely-phased output signals of the capacitance-to-voltage converter.

According to one specific embodiment of the present invention, the filter unit is configured to output the averaged differential signal at an output frequency, and output frequency Fout corresponds to a fraction of frequency Fs of the oppositely-phased output signals of the capacitance-to-voltage converter: Fout=Fs/n where n={1, 2, . . . }.

This may yield the technical advantage that a precisely averaged differential signal and, associated therewith, a precise value of the DC voltage offset may be determined. With the output frequency being maximally equal to the periodicity of the oppositely-phased output signals of the capacitance-to-voltage converter, the averaging of the sampled differential signal may take place at least over a period, or over a plurality of successive periods, of the oppositely-phased output signals of the capacitance-to-voltage converter. In this way, a precise averaging and, associated therewith, a precise determination of the DC voltage offset may be achieved.

According to one specific embodiment of the present invention, the feedback circuit further includes a feedback capacitor element, the feedback capacitor element being configured to feed the averaged differential signal into the capacitance-to-voltage converter.

This may yield the technical advantage that the averaged differential signal may be fed in the form of a charge via the feedback capacitor element into the input connections of the capacitance-to-voltage converter. In this way, the fed averaged differential signals may be processed by the capacitance-to-voltage converter as feedback input signals.

According to one specific embodiment of the present invention, the filter unit is designed as a filter with a finite impulse response.

This may yield the technical advantage that an efficient and precise filter unit may be provided.

According to one specific embodiment of the present invention, the filter unit is designed as a passive filter element.

This may yield the technical advantage that no additional power is required for operating the filter unit. As a result, a preferably power-saving readout circuit may be provided.

According to one second aspect of the present invention, a sensor system is provided including a capacitive differential sensor including a periodic output signal and a readout circuit according to one of the preceding specific embodiments.

This may yield the technical advantage that an improved sensor system including a readout circuit may be provided with the aforementioned technical advantages.

According to one specific embodiment of the present invention, the sensor is designed as a capacitive rotation rate sensor.

This may yield the technical advantage that an improved sensor system including a capacitive rotation rate sensor may be provided with the aforementioned technical advantages.

### BRIEF DESCRIPTION OF THE DRAWINGS

Exemplary embodiments of the present invention are explained with reference to the figures.

FIG. 1 schematically shows a representation of a sensor system including a readout circuit according to one specific embodiment of the present invention.

FIG. 2 shows a block diagram of a signal processing of a readout circuit according to one specific embodiment of the present invention.

FIG. 3 shows a time switch diagram of a signal processing of a readout circuit according to one specific embodiment of the present invention.

### DETAILED DESCRIPTION OF EXAMPLE EMBODIMENTS

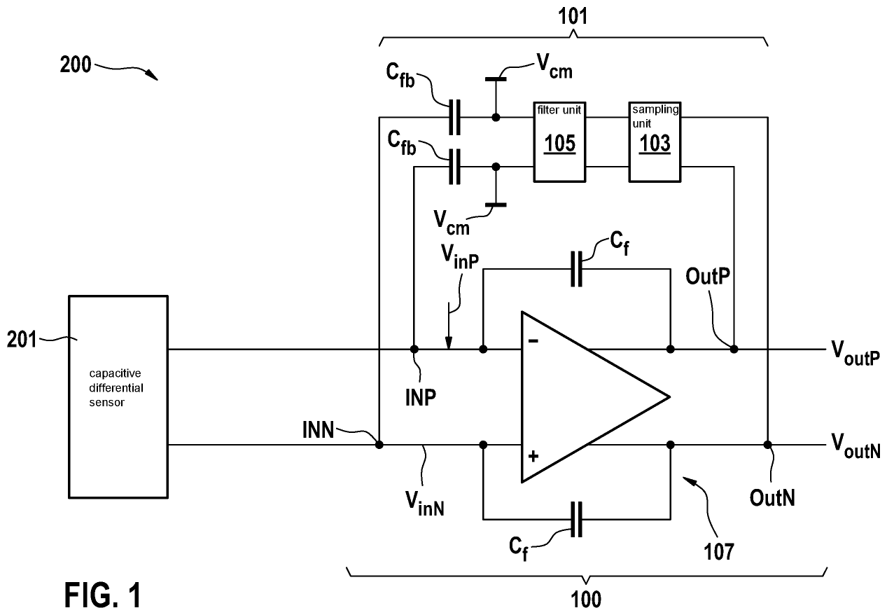

FIG. 1 schematically shows a representation of a sensor system 200 including a readout circuit 100 according to one specific embodiment.

In the specific embodiment shown, sensor system 200 includes a capacitive differential sensor 201 and a readout circuit 100. Readout circuit 100 includes a capacitance-to-voltage converter 107 and a feedback circuit 101.

Capacitance-to-voltage converter 107 includes two input connections INP, INN and two output connections OutP, OutN and is configured to amplify capacitive output signals of capacitive differential sensor 201 and to convert them into correspondingly amplified voltage signals.

Capacitance-to-voltage converter 107 further includes two further feedback capacitors Cf, which are configured according to the related art to feed a capacitive feedback signal in the form of signal charges into input connections INP, INN.

Feedback circuit 101 is connected in parallel to further feedback capacitors Cf and is interconnected with input connections INP, INN and output connections OutP, OutN to capacitance-to-voltage converter 107. Feedback circuit 101 includes a sampling unit 103 and a filter unit 105, which are interconnected in series to each other. In the specific embodiment shown, feedback circuit 101 further includes two feedback capacitors Cfb and two common-mode voltage sources VCM, each of which is interconnected in a signal processing direction D of feedback circuit 101 downstream from filter unit 105.

Feedback circuit 101 includes two signal processing paths each, which are interconnected separately from one another in each case between input connections INP, INN and respective output connections OutP, OutN.

Capacitive differential sensors 201 include periodic output signals and may be designed, for example, as a capacitive rotation rate sensor. The periodic capacitive output signals of sensor 201 are fed in the form of corresponding signal charges as corresponding input signals VinP, VinN into input connections INP, INN of capacitance-to-voltage converter 107. Capacitance-to-voltage converter 107 amplifies input signals VinP, VinN and converts these into corresponding voltage signals and outputs corresponding output signals VoutP, VoutN. Output signals VoutP, VoutN in this case exhibit the periodicity of the periodic output signals of capacitive sensor 201 and are completely differential, that is, as completely oppositely-phased output signals.

The two oppositely-phased output signals from the two output connections OutP, OutN are conducted by the two signal processing paths of feedback circuit 101 into sampling unit 103. Sampling unit 103 is configured to form a differential signal of the two oppositely-phased output signals and to sample the differential signal at a sampling frequency and to form a corresponding sampled differential signal. The sampled differential signal is transferred to filter unit 105, which is configured to average the sampled differential signal and to output an averaged differential signal at an output frequency. In the specific embodiment shown, a common-mode voltage signal is superposed on the averaged differential signal and the two feedback capacitors Cfb are charged in each case with the averaged differential signal and the superposed common-mode voltage signal. Feedback capacitors Cfb in this case form with the averaged differential signal and the common-mode voltage signals corresponding signal charges, which are fed as feedback signals into input connections INP, INN of capacitance-to-voltage converter 107.

Filter unit 105 may, for example, be designed as a filter with a finite impulse response FIR. Alternatively or in addition, filter unit 105 may be operated as a passive filter.

Common-mode voltage source VCM may, for example, be a grounding voltage. Alternatively, the common-mode voltage may also be generated as a reference proportional to the operating voltage of capacitance-to-voltage converter 107.

Feedback circuit 101 is thus configured to convert periodic, oppositely-phased voltage signals of capacitance-to-voltage converter 107 into an averaged differential signal, which corresponds to a difference between the two oppositely-phased output signals of capacitance-to-voltage converter 107, to superpose common-mode voltage signals thereon and to feed corresponding signal charges as feedback into input connections INP, INN of capacitance-to-voltage converter 107.

By feeding the averaged differential signal into input connections INP, INN of capacitance-to-voltage converter 107, it is possible to reduce or neutralize the DC voltage offset of capacitance-to-voltage converter 107. In addition, a thermal noise of capacitance-to-voltage converter 107 may be reduced.

By feeding common-mode voltage signals VCM into input connections INP, INN of capacitance-to-voltage converter 107, it is possible to control the voltage levels prevailing at input connections INP, INN of capacitance-to-voltage converter 107 in order to thereby be able to operate capacitance-to-voltage converter 107 in a preferred operating state.

In the specific embodiment shown, feedback circuit 101 is designed as a first-order feedback loop and the feedback signals, made up of the averaged differential signal and common-mode voltage signals VCM, may be fed as corresponding signal charges into input connections INP, INN of capacitance-to-voltage converter 107. In this way, the control of the common-mode voltage at input connections INP, INN may be designed in a technically simple manner as a charge sharing between input connections INP, INN and the common-mode voltage signals of feedback capacitors Cfb of feedback circuit 101.

Readout circuit 100 may be designed, in particular, as an application-specific integrated circuit ASIC.

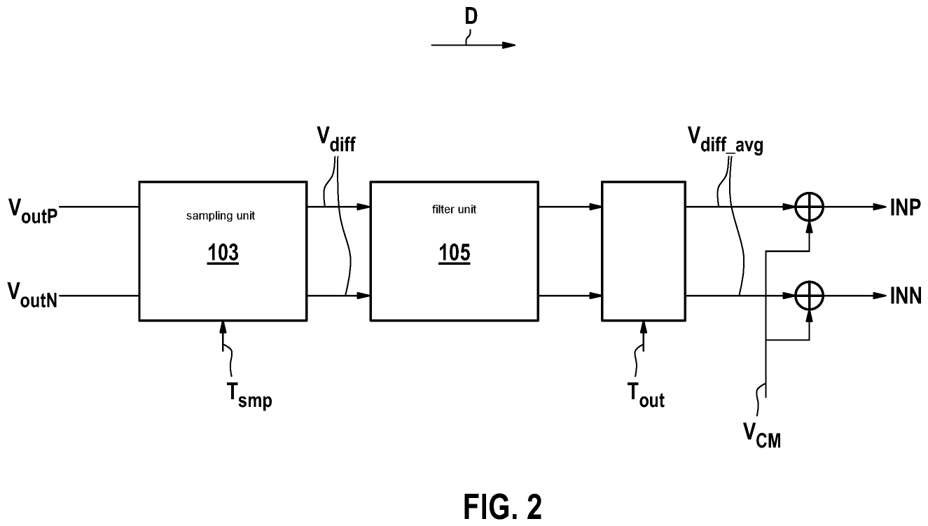

FIG. 2 shows a block diagram of a signal processing of a readout circuit 100 according to one specific embodiment.

For the purpose of signal processing of output signals VoutP, VoutN of capacitive voltage converter 107 by feedback circuit 101, output signals VoutP, VoutN are introduced along a signal processing direction D initially into sampling unit 103. Sampling unit 103 forms from the two oppositely-phased output signals VoutP, VoutN, both of which are periodic signals and which exhibit the periodicity of the periodic output signals of capacitive differential sensor 201, a corresponding differential signal, which corresponds to a difference between the two oppositely-phased output signals VoutP, VoutN. Sampling unit 103 samples averaged differential signal Vdiff according to a sampling frequency Fsmp and a temporal sampling period Tsmp=1/Fsmp, and forms a sampled differential signal. Sampling frequency Fsmp in this case may correspond to an integer multiple of frequency Fs of periodic output signals VoutP, VoutN of capacitance-to-voltage converter 107, periodic output signals VoutP, VoutN including a corresponding period Ts=1/Fs. Frequency Fs of output signals VoutP, VoutN in this case corresponds to the frequency of the periodic output signals of capacitive differential sensor 201.

Sampling unit 103 subsequently passes sampled differential signal Vdiff to filter unit 105. Filter unit 105 averages sampled differential signal Vdiff and forms an averaged differential signal Vdiff_avg. Filter unit 105 outputs averaged differential signal Vdiff_avg as the output signal according to an output frequency Fout. The output signal in this case includes an output period Tout=1/Fout according to output frequency Fout. Output frequency Fout in this case may correspond to a fraction of frequency Fs of oppositely-phased output signals VoutP, VoutN of capacitance-to-voltage converter 107 and may satisfy the following relation, Fout=Fs/n where n=1,2, . . . .

Thus, an averaging of averaged differential signal Vdiff may be carried out for at least one period of periodic output signals VoutP, VoutN of capacitance-to-voltage converter 107 as a function of output frequency Fout.

A common-mode voltage signal VCM is subsequently superposed on each averaged differential signals Vdiff_avg and output to respective input connections INP, INN. Feedback capacitors Cfb are not represented in FIG. 2. Following the explanation with respect to FIG. 1, superposed differential signals Vdiff_avg and common-mode voltage signals VCM are fed in the form of corresponding signal charges into input connections INP, INN.

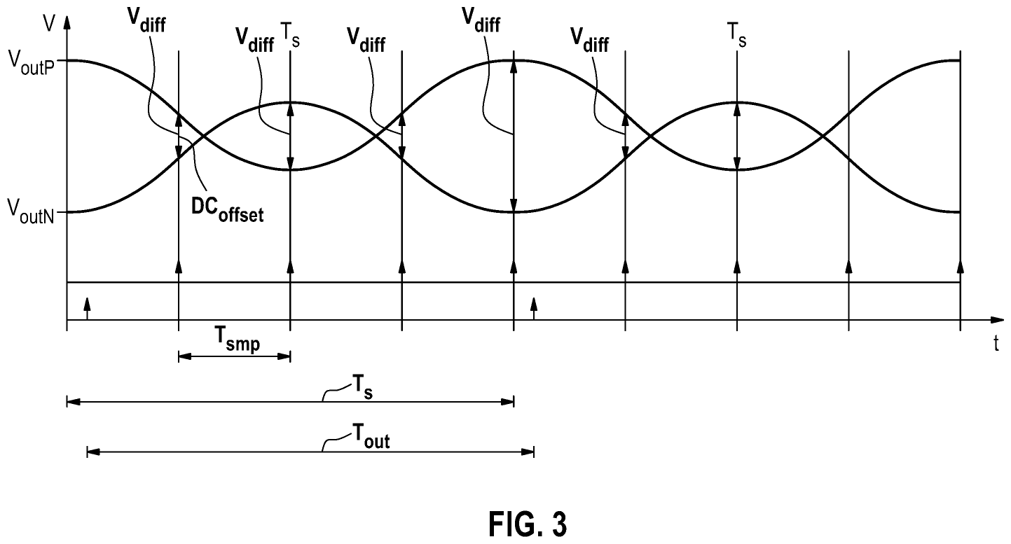

FIG. 3 shows a time switch diagram of a signal processing of a readout circuit 100 according to one specific embodiment.

FIG. 3 shows a temporal profile of the two periodic, oppositely-phased output signals VoutP, VoutN of capacitance-to-voltage converter 107. The two output signals VoutP, VoutN are sinusoidal and completely oppositely-phased. The two output signals VoutP, VoutN further include a mutual shift in the form of a DC voltage offset DC offset [sic], which is shown by the non-vanishing difference in the zero-passage of the two output signals VoutP, VoutN.

Differential signals Vdiff, which are generated by sampling unit 103 as the difference between the two oppositely-phased output signals VoutP, VoutN, are further shown in FIG. 3 for various sampling points in time. Differential signal Vdiff formed by sampling unit 103 is subsequently sampled according to a sampling frequency Fsmp in the sampling period Tsmp=1/Fsmp shown. Sampling frequency Fsmp in this case corresponds to at least double frequency Fs of periodic output signals VoutP, VoutN. In the specific embodiment shown, sampling frequency Fsmp corresponds to quadruple frequency Fs of output signals VoutP, VoutN, as a result of which sampling period Tsmp shown corresponds to a quarter of period Ts=1/Fs of periodic output signals VoutP, VoutN.

Sampled differential signal Vdiff is averaged by filter unit 105 as explained above and is output at an output frequency Fout and with a corresponding output period Tout=1/Fout. In the specific embodiment shown, output frequency Fout=1/Tout corresponds to frequency Fs=1/Ts of output signals VoutP, VoutN, as a result of which output period Tout also corresponds to period Ts of output signals VoutP, VoutN. Alternatively, output frequency Fout may correspond to a fraction of frequency Fs, that is, Fs/n where n=1,2, . . . . In the specific embodiment shown in FIG. 3, sampled differential signal Vdiff is thus averaged by filter unit 105 for a period Ts of output signals VoutP, VoutN. At a lower output frequency Tout, sampled differential signal Vdiff may, in contrast, be averaged for an integer multiple of the period of output signals VoutP, VoutN and a corresponding averaged differential signal Vdiff_avg may be generated.

Averaged differential signal Vdiff_avg in this case describes the DC voltage offset DC-offset [sic].

What is claimed is:

1. A readout circuit for a capacitive differential sensor having periodic output signals, comprising:
a capacitance-to-voltage converter configured to output signals of the sensor; and
a feedback circuit including a sampling unit and a filter unit, the sampling unit configured to sample a differential signal of two oppositely-phased output signals of the capacitance-to-voltage converter and to generate a sampled differential signal, the filter unit is configured to average the sampled differential signal and to generate an averaged differential signal, and the feedback circuit is configured to feed the averaged differential signal as feedback into the capacitance-to-voltage converter.

2. The readout circuit as recited in claim 1, wherein the feedback circuit is further configured to superpose a common-mode voltage signal on the averaged differential signal.

3. The readout circuit as recited in claim 1, wherein the sampling unit is configured to sample the differential signal at a predetermined sampling frequency, and the sampling frequency is at least double a frequency of the oppositely-phased output signals of the capacitance-to-voltage converter.

4. The readout circuit as recited in claim 3, wherein the sampling unit is configured to sample the differential signal at a sampling frequency which is an integer multiple of the frequency of the output signals.

5. The readout circuit as recited in claim 1, wherein the filter unit is configured to output the averaged differential signal at an output frequency, the output frequency corresponding to a fraction of the frequency of the oppositely-phased output signals of the capacitance-to-voltage converter: Fout=Fs/n where n={1,2, . . . }, Fout being the output frequency of the average differential signal, and Fs being the frequency of the oppositely-phased output signal of the capacitance-to-voltage converter.

6. The readout circuit as recited in claim 1, wherein the feedback circuit further includes at least one feedback capacitor element, the feedback capacitor element being configured to feed the averaged differential signal into the capacitance-to-voltage converter.

7. The readout circuit as recited in claim 1, wherein the filter element is a filter with a finite impulse response (FIR).

8. The readout circuit as recited in claim 1, wherein the filter unit is a passive filter element.

9. A sensor system, comprising:
a capacitive differential sensor having periodic output signals; and
a readout circuit including:
a capacitance-to-voltage converter configured to output signals of the sensor, and
a feedback circuit including a sampling unit and a filter unit, the sampling unit configured to sample a differential signal of two oppositely-phased output signals of the capacitance-to-voltage converter and to generate a sampled differential signal, the filter unit is configured to average the sampled differential signal and to generate an averaged differential signal, and the feedback circuit is configured to feed the averaged differential signal as feedback into the capacitance-to-voltage converter.

10. The sensor system as recited in claim 9, wherein the sensor is a capacitive rotation rate sensor.
